(19) United States
(12) Patent Application Publication
(10) Pub. No.: US 2023/0038110 A1
(43) Pub. Date: Feb. 9, 2023

(54) COMPOSITION FOR REMOVING EDGE BEADS FROM METAL CONTAINING RESISTS, AND METHOD OF FORMING PATTERNS INCLUDING STEP OF REMOVING EDGE BEADS USING THE COMPOSITION

(71) Applicants: SAMSUNG SDI CO., LTD., Yongin-si (KR); SAMSUNG ELECTRONICS CO., LTD., Suwon-si (KR)

(72) Inventors: Minyoung LEE, Suwon-si (KR); Hyungrang MOON, Suwon-si (KR); Ryunmin HEO, Suwon-si (KR); Minsoo KIM, Suwon-si (KR); Youngkwon KIM, Suwon-si (KR); Jaehyun KIM, Suwon-si (KR); Changsoo WOO, Suwon-si (KR); Jung Min CHOI, Suwon-si (KR); Moohyun KOH, Hwaseong-si (KR); Jungah KIM, Hwaseong-si (KR); Sungan DO, Hwaseong-si (KR); Sang Won BAE, Suwon-si (KR); Hoon HAN, Hwaseong-si (KR); SukKoo HONG, Hwaseong-si (KR)

(21) Appl. No.: 17/858,921

(22) Filed: Jul. 6, 2022

(30) Foreign Application Priority Data
Jul. 8, 2021 (KR) 10-2021-0089812
May 18, 2022 (KR) 10-2022-0061045

(51) Int. Cl. G03F 7/16; G03F 7/11

(52) U.S. Cl. CPC G03F 7/168; G03F 7/11

(57) ABSTRACT

A composition for removing edge beads from a metal-containing resist, and a method of forming patterns including step of removing edge beads using the same are provided. The composition for removing edge beads from a metal-containing resist includes an organic solvent, and a heptagonal ring compound substituted with at least one hydroxyl group (—OH). The heptagonal ring compound has at least two double bonds in the ring.

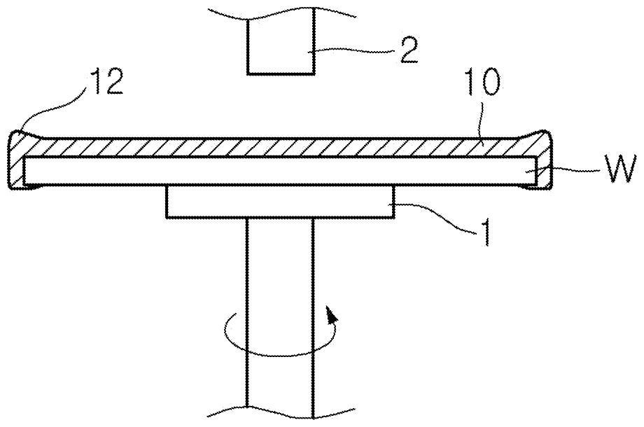

### CROSS-REFERENCE TO RELATED APPLICATIONS

This application claims priority to and the benefit of Korean Patent Application No. 10-2021-0089812, filed in the Korean Intellectual Property Office on Jul. 8, 2021, and Korean Patent Application No. 10-2022-0061045 filed in the Korean Intellectual Property Office on May 18, 2022, the entire contents of both applications are hereby incorporated by reference.

### BACKGROUND

### 1. Field

Aspects of one or more embodiments of the present disclosure relate to a composition for removing edge beads from metal-containing resists, and a method of forming patterns including step (e.g., act or task) of removing edge beads utilizing the composition.

### 2. Description of the Related Art

In recent years, a semiconductor industry has been accompanied by a substantially continuous reduction of critical dimensions, and this dimensional reduction requires new types (kinds) of high-performance photoresist materials and a patterning method that satisfy a demand for processing and patterning with increasingly smaller features.

In some embodiments, with the recent rapid development of the semiconductor industry, a semiconductor device is required that has a fast operation speed and a large storage capacity, and in line with this requirement, process technology for improving integration, reliability, and a response speed of the semiconductor device is being developed. For example, it is important to accurately control/implant impurities in working regions of a silicon substrate and to interconnect these regions to form a device and an ultra-high-density integrated circuit, which may be achieved by a photolithographic process. For example, it is important to integrate the photolithographic process including coating a photoresist on the substrate, selectively exposing it to ultraviolet (UV) (including extreme ultraviolet (UV)), electron beams, X rays, and/or the like, and then, developing it.

For example, in the process of forming the photoresist layer, the resist is coated on the substrate, primarily while rotating the silicon substrate, wherein the resist is coated on an edge and rear surface of the substrate, which may cause indentation or pattern defects in the subsequent semiconductor processes such as etching and/or ion implantation processes. Accordingly, a process of stripping and removing the photoresist coated on the edge and rear surface of the silicon substrate by utilizing a thinner composition, for example, an EBR (edge bead removal) process is performed. The EBR process requires a composition that exhibits excellent or suitable solubility for the photoresist and effectively removes beads and the photoresist remaining in the substrate and generates substantially no resist residue.

### SUMMARY

An aspect of one or more embodiments of the present disclosure is directed toward a composition for removing edge beads from a metal-containing resist.

Another aspect of one or more embodiments of the present disclosure is directed toward a method of forming patterns including the step (e.g., the act or task) of removing the edge beads utilizing the composition.

Additional aspects will be set forth in part in the description which follows and, in part, will be apparent from the description, or may be learned by practice of the presented embodiments of the disclosure.

The composition for removing edge beads from the metal-containing resist according to an embodiment includes an organic solvent and a heptagonal ring compound substituted with at least one hydroxyl group (—OH), wherein the heptagonal ring compound has at least two double bonds in the ring.

The heptagonal ring compound may be substituted with one or two hydroxyl groups (—OH).

The heptagonal ring compound may have three double bonds.

The heptagonal ring compound may be represented by Chemical Formula 1.

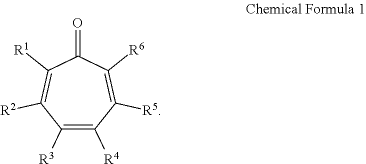

In Chemical Formula 1,

R¹ to R⁶ may each independently be hydrogen, a halogen, a hydroxy group, an amino group, a substituted or unsubstituted C1 to C30 amine group, a substituted or unsubstituted C1 to C10 alkyl group, or a substituted or unsubstituted C6 to C20 aryl group, and

at least one of R¹ to R⁶ may be a hydroxy group.

The heptagonal ring compound may be selected from the formulas of Group 1.

### Group 1

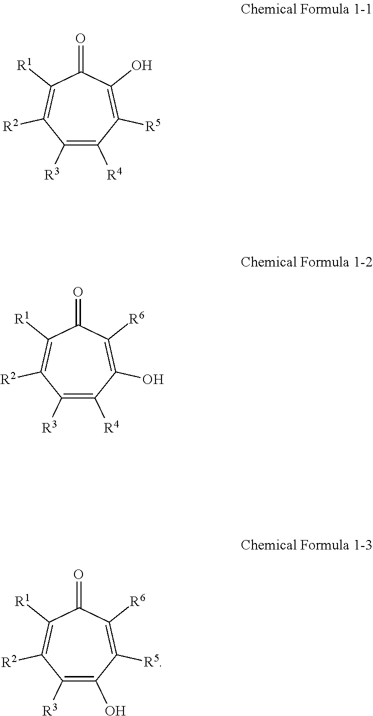

In Group 1,

R¹ to R⁶ may each independently be hydrogen, a halogen, an amino group, a substituted or unsubstituted C1 to C30 amine group, a substituted or unsubstituted C1 to C10 alkyl group, or a substituted or unsubstituted C6 to C20 aryl group.

The heptagonal ring compound may be 2-hydroxy-2,4,6-cycloheptatrien-1-one.

The composition for removing edge beads from the metal-containing resist may include about 50 to about 99.99 wt % of the organic solvent; and about 0.01 to about 50 wt % of the heptagonal ring compound.

The metal compound included in the metal-containing resist may include at least one of an alkyl tin oxo group and/or an alkyl tin carboxyl group.

The metal compound included in the metal-containing resist may be represented by Chemical Formula 3.

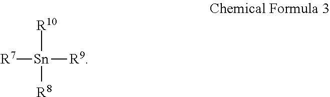

In Chemical Formula 3,

R⁷ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 or C30 arylalkyl group, or —R^{a}—O—R^{b} (wherein R^{a} may be a substituted or unsubstituted C1 to C20 alkylene group and R^{b} may be a substituted or unsubstituted C1 to C20 alkyl group),

R⁸ to R¹⁰ may each independently be —OR^{c} or —OC(═O)R^{d},

R^{c} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or one or more combinations thereof, and

R^{d} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or one or more combinations thereof.

A method of forming patterns according to another embodiment includes coating a metal-containing resist composition on a substrate, coating the aforementioned composition for removing edge beads from the metal-containing resist along the edge of the substrate, drying and heating the resultant (i.e., the substrate after the coating steps) to form a metal-containing resist film on the substrate, and exposing and developing the resultant (i.e., the substrate after the drying and heating step) to form a resist pattern.

The method of forming patterns may further include coating the aforementioned composition for removing edge beads from the metal-containing resist along the edge of the substrate after exposing and developing.

The composition for removing edge beads from the metal-containing resist according to an embodiment may reduce the metal-based contamination inherent in the metal-containing resist and may remove the resist coated on the edge and rear surface of the substrate, thereby satisfying requirements of processing and patterning of smaller features (dimensions).

### BRIEF DESCRIPTION OF THE DRAWINGS

The accompanying drawing is included to provide a further understanding of of the present disclosure, and is incorporated in and constitutes a part of this specification. The drawing illustrates example embodiments of the present disclosure and, together with the description, serves to explain principles of present disclosure. In the drawings:

The drawing is a schematic view of a photoresist coating apparatus.

### DETAILED DESCRIPTION

The present disclosure may be modified in many alternate forms, and thus specific embodiments will be exemplified in the drawing and described in more detail. It should be understood, however, that it is not intended to limit the present disclosure to the particular forms disclosed, but rather, is intended to cover all modifications, equivalents, and alternatives falling within the spirit and scope of the present disclosure.

Hereinafter, embodiments of the present disclosure will be described in more detail with reference to the accompanying drawing. In the following description of the present disclosure, the generally used/generally available functions or constructions may not be described.

In order to clearly and succinctly illustrate the present disclosure, some description and relationships may be omitted, and throughout the disclosure, the same or similar configuration elements are designated by the same reference numerals. Also, because the size and thickness of each configuration shown in the drawing may be arbitrarily shown for better understanding and ease of description, the present disclosure is not necessarily limited thereto.

In the drawing, the thickness of layers, films, panels, regions, etc., may be exaggerated for clarity. In the drawing, the thickness of a part of layers or regions, etc., may be exaggerated for clarity. It will be understood that when an element such as a layer, film, region, or substrate is referred to as being “on” another element, it can be directly on the other element or intervening elements may also be present.

In the present disclosure, “substituted” refers to replacement of a hydrogen atom by deuterium, a halogen group, a hydroxyl group, an amino group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a cyano group. “Unsubstituted” refers to a hydrogen atom that remains as a hydrogen atom without being replaced by another substituent.

In the present disclosure, unless otherwise defined, the term “heptagonal ring compound” refers to a compound having a structure in which the terminal atoms constituting a molecule are linked to each other to form a heptagonal ring, and according to the type or kind of atoms forming the ring, it may be classified as a ‘carbocyclic compound’ or a ‘heterocyclic compound’.

The ‘carbocyclic compound’ refers to a compound in which a ring-forming atom is only carbon.

The ‘heterocyclic compound’ refers to a compound including a hetero atom in addition to carbon atoms forming a ring.

The hetero atom that may be contained in the ‘heterocyclic compound’ may include, but is not limited to, N, O, S, P, Si, and/or the like.

In the present disclosure, the term “alkyl group” refers to a linear or branched aliphatic hydrocarbon group, unless otherwise defined. The alkyl group may be a “saturated alkyl group” that does not contain any double or triple bonds.

The alkyl group may be a C1 to C20 alkyl group. For example, the alkyl group may be a C1 to C10 alkyl group or a C1 to C6 alkyl group. For example, a C1 to C4 alkyl group refers to an alkyl chain that contains 1 to 4 carbon atoms, and may be selected from among methyl, ethyl, propyl, iso-propyl, n-butyl, iso-butyl, sec-butyl, and t-butyl groups.

Examples of the alkyl group include a methyl group, an ethyl group, a propyl group, an isopropyl group, a butyl group, an isobutyl group, a t-butyl group, a pentyl group, a hexyl group, a cyclopropyl group, a cyclobutyl group, a cyclopentyl group, a cyclohexyl group, etc.

In the present disclosure, the term “cycloalkyl group” refers to a monovalent cyclic aliphatic hydrocarbon group unless otherwise defined.

In the present disclosure, the term “alkenyl group”, unless otherwise defined, is a linear or branched aliphatic hydrocarbon group, and refers to an aliphatic unsaturated alkenyl group containing one or more double bonds.

In the present disclosure, the term “alkynyl group”, unless otherwise defined, is a linear or branched aliphatic hydrocarbon group, and refers to an unsaturated alkynyl group containing one or more triple bonds.

In the present disclosure, “aryl group” refers to a substituent in which all elements of a cyclic substituent have p-orbitals, and these p-orbitals form a conjugate.

It may include monocyclic or fused ring polycyclic (i.e., rings that share adjacent pairs of carbon atoms) functional groups.

The drawing is a schematic view of a photoresist coating apparatus.

Referring to the drawing, a substrate support portion 1 on which a substrate W is placed is provided, and the substrate support portion 1 includes a spin chuck or a spin coater.

The substrate support portion 1 rotates in a first direction (e.g., a rotational direction or a clockwise direction) at a set or predetermined rotation speed, and provides a centrifugal force to the substrate W. A spray nozzle 2 is on the substrate support portion 1, and the spray nozzle 2 is located in an atmospheric area deviating from the upper portion of the substrate W and moves to the upper portion of the substrate W during the solution supply step (e.g., act or task) to spray a photoresist solution 10. Accordingly, the photoresist solution 10 is coated on the surface of the substrate by the centrifugal force. Then, the photoresist solution 10 supplied to the center of the substrate W is coated while being spread to the edge of the substrate W by the centrifugal force, and a portion thereof is moved to the side surface of the substrate and even the lower surface of the edge of the substrate as shown.

For example, in the coating process, the photoresist solution 10 is primarily coated by a spin coating method. By supplying a set or predetermined amount of viscous photoresist solution 10 to the center of the substrate W, the solution 10 gradually spreads toward the edge of the substrate W by the centrifugal force.

Therefore, the thickness of the photoresist is formed to be flat by the rotation speed of the substrate support portion 1.

However, as the solvent evaporates, the viscosity gradually increases, and a relatively large amount of photoresist is accumulated on the edge of the substrate W by the action of surface tension. For example, the photoresist is accumulated up to the lower surface of the edge of the substrate W, which is referred to as an edge bead or edge beads 12.

Hereinafter, a composition for removing edge beads from a metal-containing resist according to an embodiment will be described.

The composition for removing edge beads from the metal-containing resist according to an embodiment of the present disclosure includes an organic solvent and a heptagonal ring compound substituted with at least one hydroxy group (—OH), wherein the heptagonal ring compound has at least two double bonds in the ring.

The “double bond” is included in at least two in the ring, and a form in which the double bond is continuously included is excluded due to the nature of the rigid structure of the heptagonal ring compound. The ‘having at least two double bonds in the ring’ refers to two double bonds that are included via at least one single bond.

The composition for removing edge beads from the metal-containing resist includes a heptagonal ring compound substituted with a hydroxyl group (—OH), and the hydroxyl group (—OH) is coordinated with the metal-containing resist, and by coating the composition including the same, the metal-containing resist may be effectively removed.

For example, the heptagonal ring compound may be substituted with one or two hydroxyl groups (—OH).

The heptagonal ring compound may have three double bonds.

For example, the heptagonal ring compound may be represented by Chemical Formula 1.

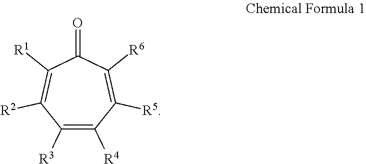

In Chemical Formula 1 and Chemical Formula 2,

R¹ to R⁶ may each independently be hydrogen, a halogen, a hydroxy group, an amino group, a substituted or unsubstituted C1 to C30 amine group, a substituted or unsubstituted C1 to C10 alkyl group, or a substituted or unsubstituted C6 to C20 aryl group, and

at least one of R¹ to R⁶ may be a hydroxy group.

As an example, the heptagonal ring compound may be selected from the chemical formulas of Group 1.

### Group 1

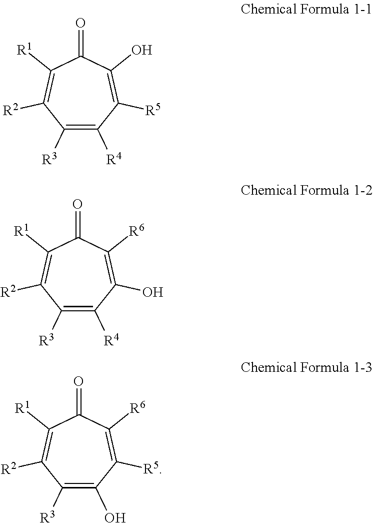

In Group 1,

R¹ to R⁶ may each independently be hydrogen, a halogen, an amino group, a substituted or unsubstituted C1 to C30 amine group, a substituted or unsubstituted C1 to C10 alkyl group, or a substituted or unsubstituted C6 to C20 aryl group.

For example, the heptagonal ring compound may be 2-hydroxy-2,4,6-cycloheptatrien-1-one, or tropolone.

In an embodiment, the composition for removing edge beads from the metal-containing resist includes about 50 to about 99.99 wt % of organic solvent and about 0.01 to about 50 wt % of the aforementioned heptagonal ring compound.

In an embodiment, the composition for removing edge beads from the metal-containing resist may include the aforementioned heptagonal ring compound in an amount of about 0.05 to 40 wt %, about 0.5 to 30 wt %, or about 1 to 20 wt %.

The organic solvent included in the composition for removing edge beads from the metal-containing resist according to an embodiment may be for example propylene glycol methyl ether (PGME), propylene glycol methyl ether acetate (PGMEA), propylene glycol butyl ether (PGBE), ethylene glycol methyl ether, diethylglycolethylmethylether, dipropylglycoldimethylether, ethanol, 2-butoxyethanol, n-propanol, isopropanol, n-butanol, isobutanol, hexanol, ethylene glycol, propylene glycol, heptanone, propylene carbonate, butylene carbonate, diethyl ether, dibutyl ether, ethyl acetate, methyl 3-m ethoxypropionate, ethyl 3-ethoxypropionate, diisopentyl ether, xylene, acetone, methylethylketone, methylisobutylketone, tetrahydrofuran, dimethylsulfoxide, dimethyl formamide, acetonitrile, diacetone alcohol, 3,3-dimethyl-2-butanone, N-methyl-2-pyrrolidone, dimethyl acetamide, cyclohexanone, methyl-2-hydroxy-2-methylpropanoate (HBM), gamma butyrolactone (GBL), 1-butanol (n-butanol), ethyl lactate (EL), diene butylether (DBE), diisopropyl ether (DIAE), acetylacetone, butyl lactate (n-butylactate), 4-methyl-2-pentenol (or referred to as methyl isobutyl carbinol (MIBC)), 1-methoxy-2-propanol, 1-ethoxy-2-propanol, toluene, xylene, methylethylketone, cyclopentanone, cyclohexanone, 2-hydroxyethyl propionate, 2-hydroxy-2-methylethyl propionate, ethoxyethyl acetate, hydroxyethyl acetate, 2-hydroxy-3-methylmethyl butanoate, 3-methoxymethyl propionate, 3-methoxyethyl propionate, 3-ethoxyethyl propionate, 3-ethoxymethyl propionate, methyl pyruvate, ethyl pyruvate, ethyl acetate, butyl acetate, ethyl lactate, methyl-2-hydroxyisobutyrate, methoxy benzene, n-butyl acetate, 1-methoxy-2-propyl acetate, methoxyethoxy propionate, ethoxyethoxy propionate, or a mixture thereof, but is not limited thereto.

The composition for removing edge beads from the metal-containing resist according to the present disclosure may be effective in removing metal-containing resists, and/or undesirable metal residues such as tin-based metal residues.

The metal compound included in the metal-containing resist may include at least one of an alkyl tin oxo group and/or an alkyl tin carboxyl group.

For example, the metal compound included in the metal-containing resist may be represented by Chemical Formula 3.

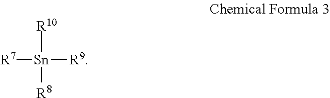

In Chemical Formula 3,

R⁷ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 or C30 arylalkyl group, or —R^{a}—O—R^{b} (wherein R^{a} is a substituted or unsubstituted C1 to C20 alkylene group and R^{b} is a substituted or unsubstituted C1 to C20 alkyl group),

R⁸ to R¹⁰ may each independently be —OR^{c} or —OC(═O)R^{d},

R^{c} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or one or more combinations thereof, and

R^{d} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or one or more combinations thereof.

In some embodiments, a method of forming patterns includes the step (e.g., the act or task) of removing the edge beads utilizing the aforementioned composition for removing edge beads from the metal-containing resist. For example, the manufactured pattern may be a photoresist pattern. More specifically, it may be a negative photoresist pattern.

The method of forming patterns according to an embodiment includes coating a metal-containing resist composition on a substrate, coating the aforementioned composition for removing edge beads from the metal-containing resist along the edge of the substrate, drying and heating the resultant to form a metal-containing resist film on the substrate, and exposing and developing the resultant to form a resist pattern.

For example, the forming of patterns utilizing the metal-containing resist composition may include coating a metal-containing resist composition on a substrate on which a thin film is formed by spin coating, slit coating, inkjet printing, etc., and drying the coated metal-containing resist composition to form a photoresist film. The metal-containing resist composition may include a tin-based compound, for example, the tin-based compound may include at least one of an alkyl tin oxo group and/or an alkyl tin carboxyl group.

Subsequently, the coating of the aforementioned composition for removing edge beads from the metal-containing resist may be performed, and for example, the composition for removing edge beads from the metal-containing resist along the edge of the substrate may be coated while rotating the substrate at an appropriate or suitable speed (e.g., 500 rpm or more).

Subsequently, a first heat treatment process of heating the substrate, on which the photoresist film is formed, is performed. The first heat treatment process may be performed at a temperature of about 80° C. to about 120° C. In this process, the solvent is evaporated and the photoresist film may be more firmly adhered to the substrate.

And the photoresist film is selectively exposed.

Examples of light that may be utilized in the exposure process may include not only light having a short wavelength such as i-line (wavelength 365 nm), KrF excimer laser (wavelength 248 nm), ArF excimer laser (wavelength 193 nm), but also EUV (light having a high energy wavelength such as EUV (Extreme UltraViolet, wavelength 13.5 nm), E-Beam (electron beam), etc.

In an embodiment, the light for exposure according to an embodiment may be short-wavelength light having a wavelength range of about 5 nm to about 150 nm, and light having a high energy wavelength such as EUV (Extreme UltraViolet, wavelength 13.5 nm), E-Beam (electron beam), etc.

In the step of forming the photoresist pattern, a negative pattern may be formed.

The exposed region of the photoresist film has a solubility different from that of the unexposed region of the photoresist film as a polymer is formed by a crosslinking reaction such as condensation between organometallic compounds.

Then, a second heat treatment process is performed on the substrate. The second heat treatment process may be performed at a temperature of about 90° C. to about 200° C. By performing the second heat treatment process, the exposed region of the photoresist film becomes difficult to dissolve in a developing solution.

For example, the photoresist pattern corresponding to the negative tone image may be completed by dissolving and removing the photoresist film corresponding to the unexposed region utilizing an organic solvent such as 2-heptanone.

The developing solution utilized in the method of forming patterns according to the embodiment may be an organic solvent, for example, ketones such as methyl ethyl ketone, acetone, cyclohexanone, or 2-haptanone, alcohols such as 4-methyl-2-propanol, 1-butanol, isopropanol, 1-propanol, or methanol, esters such as propylene glycol monomethyl ether acetate, ethyl acetate, ethyl lactate, n-butyl acetate, or butyrolactone, aromatic compounds such as benzene, xylene, or toluene, or one or more combinations thereof.

In some embodiments, the method of forming patterns may further include coating the composition for removing edge beads from the metal-containing resist after the exposing and developing. For example, the method may include coating an appropriate or suitable amount of the composition for removing edge beads from the metal-containing resist along the edge of the substrate while rotating the substrate at an appropriate or suitable speed (e.g., 500 rpm or more).

As described above, the photoresist pattern formed by exposure to not only light having a wavelength such as i-line (wavelength 365 nm), KrF excimer laser (wavelength 248 nm), ArF excimer laser (wavelength 193 nm), but also EUV (Extreme UltraViolet; wavelength 13.5 nm), and/or light having high energy such as an E-beam (electron beam) may have a thickness width of about 5 nm to about 100 nm. For example, the photoresist pattern may be formed to have a thickness width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In contrast, the photoresist pattern may have a pitch having a half-pitch of less than or equal to about 50 nm, for example less than or equal to about 40 nm, for example less than or equal to about 30 nm, for example less than or equal to about 20 nm, for example less than or equal to about 15 nm, and a line width roughness of less than or equal to about 10 nm, less than or equal to about 5 nm, less than or equal to about 3 nm, or less than or equal to about 2 nm.

Hereinafter, the present disclosure will be described in more detail through examples relating to the preparation of the aforementioned composition for removing edge beads from a metal-containing resist. However, the technical features of the present disclosure are not limited by the following examples.

Preparation of Composition for Removing Edge Beads of Metal-containing Resist

### Example 1

10 wt % of 2-hydroxy-2,4,6-cycloheptatrien-1-one (Tropolone) and 90 wt % of propylene glycol monomethyl ether acetate (PGMEA) were put in a polypropylene (PP) bottle and stirred for 12 hours to prepare a composition for removing edge beads.

### Example 2

A composition for removing edge beads was prepared in substantially the same manner as in Preparation Example 1, except that 5 wt % of 2-hydroxy-2,4,6-cycloheptatrien-1-one was utilized.

### Example 3

A composition for removing edge beads was prepared in substantially the same manner as in Preparation Example 1, except that 40 wt % of 2-hydroxy-2,4,6-cycloheptatrien-1-one was utilized.

### Comparative Example 1

A composition for removing edge beads was prepared in substantially the same manner as in Preparation Example 1, except that 10 wt % of glycerol was utilized instead of 2-hydroxy-2,4,6-cycloheptatrien-1-one.

### Comparative Example 2

A composition for removing edge beads was prepared in substantially the same manner as in Preparation Example 1, except that 10 wt % of acetic acid was utilized instead of 2-hydroxy-2,4,6-cycloheptatrien-1-one.

### Comparative Example 3

A composition for removing edge beads was prepared in substantially the same manner as in Preparation Example 1, except that 10 wt % of TBAF (tetrabutylammonium fluoride) was utilized instead of 2-hydroxy-2,4,6-cycloheptatrien-1-one.

### Preparation Example: Preparation of Organometal-Containing Photoresist Composition

An organometallic compound having a structure of Chemical Formula C was dissolved at a concentration of 1 wt % in 4-methyl-2-pentanol and then, filtered through a 0.1 μm PTFE syringe filter, obtaining a photoresist composition.

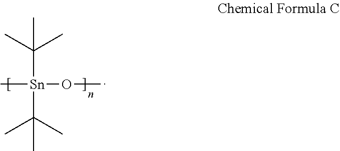

Evaluation 1: Evaluation of Residual Film Thickness (Strip Test) and Evaluation of Sn Residual Amount Before Development

1.0 mL of the organometal compound-containing photoresist composition according to preparation example was cast on a 6-inch silicon wafer, allowed to stand for 20 seconds, and then, spin-coated at 800 rpm for 30 seconds. Then, a thickness of the resist film obtained by baking at 180° C. for 60 seconds was measured by ellipsometry. While rotating the wafer on which the resist film was formed at a speed of 800 rpm, 10 mL of each composition for removing edge beads prepared in Examples 1 to 3 and Comparative Examples 1 to 3 was added along the edge and spin-coated for 5 seconds and then dried while rotating it at a speed of 1,500 rpm. Then, a thickness of each film obtained by baking at 150° C. for 60 seconds was re-measured by the ellipsometry method, and a thickness change before and after the edge bead removal process was checked and evaluated according to the following criteria. VPD ICP-MS analysis was performed to confirm the Sn residual amount (1^{st} residual amount), and the results are shown in Table 1.

* the residual thickness is less than 2 Å: ∘, the residual thickness is more than 2 Å: X

Evaluation 2: Naked Eye Evaluation of Rear Surface Stains

After performing the edge bead removal process for the wafer on which the resist film was formed as in Evaluation 1, the surface stains of the wafer were checked utilizing KMAC-ST400DLX equipment, and at the same time (concurrently), the rear surface of the substrate was visually checked for stains before/after heat treatment at 150° C. for 60 seconds. The criteria is as follows.

* No stains before/after heat treatment: ∘, stains remain but disappear after heat treatment: Δ, stains after heat treatment: X

Evaluation 3: Evaluation of Sn Residual Amount after Development (2^{nd} Residual Amount)

After performing the edge bead removal process for the wafer on which the resist film was formed as in Evaluation 1 and exposing the wafer in a 1:1 L/S pattern with an e-Beam lithography system (JBX-9300FS, JEOL), heat-treating the wafer at 170° C. for 60 seconds, performing development with a propylene glycol methyl ether acetate (PGMEA) developing solution, heat-treating the wafer at 150° C. for 60 seconds, and treating again under the same process conditions with the composition for removing edge beads prepared from Examples 1 to 3 and Comparative Examples 1 to 3, the residual amounts of Sn (2^{nd} residual amount) in the edge portion were checked by TXRF

TABLE 1

| | | | Residual | Residual |
|---|---|---|---|---|
| | | Rear | amount | amount |
| | | surface | of Sn before | of Sn after |
| | | stains | development | development |
| | Residual | (naked | (1^{st} residual | (2^{nd} residual |
| | film | eye | amount) | amount) |
| | after | eval- | (×10¹⁰ | (×10¹⁰ |
| | strip | uation) | atoms/cm²) | atoms/cm²) |
| Example 1 | ◯ | ◯ | 18 | 34 |
| Example 2 | ◯ | ◯ | 40 | 50 |
| Example 3 | ◯ | ◯ | 8 | 12 |
| Comparative | X | Δ | 3700 | 640 |
| Example 1 | | | | |
| Comparative | X | ◯ | 1100 | 375 |
| Example 2 | | | | |
| Comparative | X | X | 5300 | 971 |
| Example 3 | | | | |

Referring to Table 1, the composition for removing the edge bead(s) from the metal-containing resists according to Examples 1 to 3 exhibited a greater improved metal removal effect compared with the composition for removing the edge bead(s) from the metal-containing resist according to Comparative Examples 1 to 3, and further promoted reduction of residual metals.

The use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein.

The photoresist coating apparatus, the metal-containing resist or any other relevant metal-containing resist manufacture, control or management devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present present disclosure as defined by the following claims and equivalents thereof.

### REFERENCE NUMERALS

1: substrate support portion
2: spray nozzle
10: photoresist solution
12: edge bead

What is claimed is:

1. A composition for removing edge beads from a metal-containing resist, the compostion comprising:
an organic solvent; and
a heptagonal ring compound substituted with at least one hydroxyl group (—OH),
wherein the heptagonal ring compound has at least two double bonds in the ring.

2. The composition of claim 1, wherein
the heptagonal ring compound is substituted with one or two hydroxyl groups (—OH).

3. The composition of claim 1, wherein
the heptagonal ring compound has three double bonds.

4. The composition of claim 1, wherein
the heptagonal ring compound is represented by Chemical Formula 1: 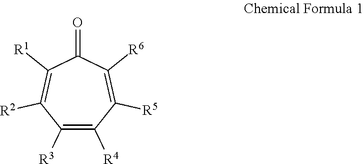
wherein, in Chemical Formula 1,
R¹ to R⁶ are each independently hydrogen, a halogen, a hydroxy group, an amino group, a substituted or unsubstituted C1 to C30 amine group, a substituted or unsubstituted C1 to C10 alkyl group, or a substituted or unsubstituted C6 to C20 aryl group, and
at least one of R¹ to R⁶ is a hydroxy group.

5. The composition of claim 1, wherein
the heptagonal ring compound is selected from the formulas of Group 1:
Group 1 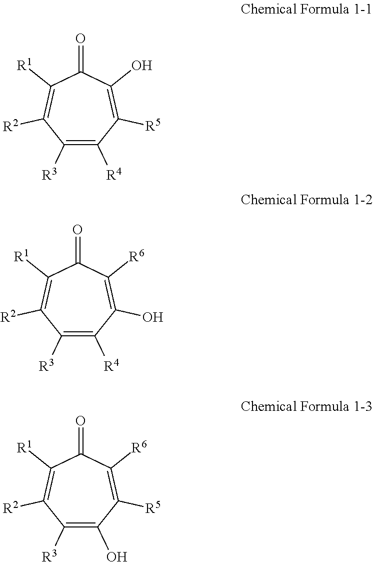
wherein, in Group 1,
R¹ to R⁶ are each independently hydrogen, a halogen, an amino group, a substituted or unsubstituted C1 to C30 amine group, a substituted or unsubstituted C1 to C10 alkyl group, or a substituted or unsubstituted C6 to C20 aryl group.

6. The composition of claim 1, wherein
the heptagonal ring compound is 2-hydroxy-2,4,6-cycloheptatrien-1-one.

7. The composition of claim 1, wherein
the composition comprises about 50 wt % to about 99.99 wt % of the organic solvent; and
about 0.01 wt % to about 50 wt % of the heptagonal ring compound.

8. The composition of claim 1, wherein
the metal compound included in the metal-containing resist comprises an alkyl tin oxo group and/or an alkyl tin carboxyl group.

9. The composition of claim 1, wherein
the metal compound included in the metal-containing resist is represented by Chemical Formula 3: 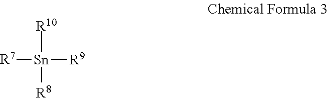
wherein, in Chemical Formula 3,
R⁷ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 or C30 arylalkyl group, or —R^{a}—O—R^{b} (wherein R^{a} is a substituted or unsubstituted C1 to C20 alkylene group and R^{b} is a substituted or unsubstituted C1 to C20 alkyl group),
R⁸ to R¹⁰ are each independently —OW or —OC(═O)R^{d},
R^{c} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{d} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

10. A method of forming patterns, the method comprising
coating a metal-containing resist composition on a substrate;
coating the aforementioned composition for removing edge beads from the metal-containing resist of claim 1 along an edge of the substrate;
drying and heating the coated resultantto form a metal-containing resist film on the substrate; and
exposing and developing the dried and heated resultant to form a resist pattern.

11. The method of claim 10, wherein
the method further comprises coating the composition for removing edge beads from the metal-containing resist along the edge of the substrate again after the exposing and developing.

12. A system of forming patterns, the system comprising
means for coating a metal-containing resist composition on a substrate;
means for coating the aforementioned composition for removing edge beads from the metal-containing resist of claim 1 along an edge of the substrate;
means for drying and heating the coated resultant to form a metal-containing resist film on the substrate; and
means for exposing and developing the dried and heated resultant to form a resist pattern.
